(19) United States
(12) Patent Application Publication
(10) Pub. No.: US 2008/0116555 A1
(43) Pub. Date: May 22, 2008

(54) Package structure of memory card and manufacturing method thereof

(75) Inventor: En-Min Jow, Hsinchu City (TW)

Correspondence Address: BACON & THOMAS, PLLC, 625 SLATERS LANE, FOURTH FLOOR, ALEXANDRIA, VA, 22314, US

(73) Assignee: En-Min JOW, Hsinchu City (TW)

(21) Appl. No.: 11/649,306

(22) Filed: Jan. 4, 2007

(30) Foreign Application Priority Data
Nov. 17, 2006 (TW) 95142676

(51) Int. Cl. H01L 23/48; H01L 23/498; H01L 21/71

(52) U.S. Cl. 257/686; 257/690; 257/784; 438/118; 257/E23.068; 257/E23.01; 257/E21.536

(57) ABSTRACT

A package structure of a memory card includes a Printed Circuit Board (PCB) and at least one chip package. Plural solder pads are set on the upper surface of the PCB, and an exposed golden finger is set on the bottom surface of the PCB. Every chip package includes at least one chip and a substrate. At least one layer of trace is set inside the substrate, and the trace has plural conductive terminals exposed on the bottom surface of the substrate. The conductive terminals are adhered to and electrically connected with the solder pads. A package method for a memory card includes: providing at least one chip package using a substrate as a chip carrier; adhering the chip package onto a PCB to electrically connect the chip package and the PCB; and covering the chip package and the PCB.

### BACKGROUND OF THE INVENTION

1. Field of the Invention

The present invention relates to a package structure of a memory card and the package method thereof, and more particularly, to a package structure of a memory card and the package method thereof which adopt a chip package and use a substrate as the chip carrier.

2. Description of the Prior Art

Memory card is a portable data storage apparatus, which is very light and handy. Along with the rapid technology progress, it has been widely applied in versatile electronic apparatus, for instance, a Personal Computer (PC), cell phone, Digital Camera (DC), Digital Video (DV) and Personal Digital Assistant (PDA), etc. The memory card has many different sizes, shapes and specifications depending on the different requirements of various applications, such as: Secure Digital card (SD card), mini SD card, micro SD card (μSD card), Multi Media Card (MMC) and Compact Flash card (CF card), etc.

Generally, a memory card includes at least one chip, such as a flash memory chip. The chip may be directly adhered and electrically connected with a Printed Circuit Board (PCB), or it may be packaged to form a chip package in advance, such as a Dynamic Random Access Memory (DRAM), and then be adhered and electrically connected with a PCB.

The conventional chip package applied for the memory card, such as a Thin Small Out-Line Package (TSOP), adopts a lead frame to carry the chip and to connect to a PCB. FIG. 1 and FIG. 2 are the cross-sectional and top-view schematic diagrams of a conventional TSOP 1 respectively. A chip 12 is set on a chip carrier 142 of a lead frame 14, which has a plurality of outer leads 144, and the chip 12 is electrically connected to the lead frame 14 via a plurality of bonding wires 16. A molding compound 18 covers the chip 12 and the chip carrier 142 and exposes the outer leads 144.

FIG. 3 is a top-view schematic diagram of a conventional PCB 2, a plurality of solder pads 22 are set on the upper surface of the PCB 2.

FIG. 4 is a top-view schematic diagram of a conventional package structure of the memory card 3, the outer leads 144 of the TSOP 1 are adhered and electrically connected with the solder pads 22 of the PCB 2. Besides, some passive elements 32, such as the transistors, capacitors and inductors are set on and electrically connected with the PCB 2.

As the above description, the TSOP that adopts a lead frame as the chip carrier is not suitable for a package structure of the Stacked-type Multi Chip Package (St. MCP) because the thickness specification of the TSOP is limited. Furthermore, the passive elements are not easy to be disposed inside the TSOP owing to the limited space. Accordingly, the functions and storage capacity of the memory card are limited and hard to be further promoted for the chip package adopting a lead frame as the chip carrier.

### SUMMARY OF THE INVENTION

In order to solve the aforementioned problems, one object of the present invention is to provide a package structure of a memory card and the package method thereof, which adopt a chip package and use a substrate as the chip carrier. It can be applied to SD card, mini SD card, μSD card, MMC and CF card, etc.

One object of the present invention is to provide a package structure of a memory card, which chip package is a flip chip package.

One object of the present invention is to provide a package structure of a memory card, which chip package is a St. MCP.

One object of the present invention is to provide a package method for a memory card, which has the advantages including simple steps, compatibility with the conventional process and easy implementation.

Accordingly, there are many advantages for the chip package of the memory card that adopts a substrate as the chip carrier according to the present invention, which include: 1. Multi layers of traces can be set inside the substrate to increase the freedom and flexibility for the package design, and the St. MCP can be applied to increase functions and storage capacity of the memory card; 2. The passive elements of the present invention can be packaged inside the chip package. Thus, more than one chip package is capable to be packaged in the same memory card to further increase functions and storage capacity of the memory card.

To achieve the purposes mentioned above, one embodiment of the present invention is to provide a package structure of a memory card, which includes: a Printed Circuit Board (PCB) having a first upper surface and a first bottom surface, wherein an exposed golden finger is set on the first bottom surface of the PCB and a plurality of solder pads are set on the first upper surface of the PCB; and at least one chip package, including: at least one chip; and a substrate, wherein the substrate has a second upper surface and a second bottom surface, the chip is set on the second upper surface, and at least one layer of trace is set inside the substrate; wherein the trace has a plurality of conductive terminals exposed on the second bottom surface, and the conductive terminals are adhered to and electrically connected with the solder pads.

To achieve the purposes mentioned above, one embodiment of the present invention is to provide a package method for a memory card, which includes: providing at least one chip package using a substrate as a chip carrier; adhering the chip package onto a PCB to electrically connect the chip package and the PCB; and covering the chip package and the PCB.

Other objects, technical contents, features and advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 and FIG. 2 are the cross-sectional and top-view schematic diagrams of a conventional Thin Small Out-Line Package (TSOP) respectively;

FIG. 3 is a top-view schematic diagram of a conventional Printed Circuit Board (PCB);

FIG. 4 is a top-view schematic diagram of a conventional package structure of the memory card;

FIG. 5 and FIG. 6 are the cross-sectional and top-view schematic diagrams of the chip package respectively according to one embodiment of the present invention;

FIG. 7 is a top-view schematic diagram of a PCB according to one embodiment of the present invention;

FIG. 8 is a top-view schematic diagram of a package structure of the memory card according to one embodiment of the present invention;

FIG. 9 and FIG. 10 are the cross-sectional schematic diagrams of the package structures of the memory card according to embodiments of the present invention;

FIG. 11 and FIG. 12 are the cross-sectional schematic diagrams of the chip packages according to embodiments of the present invention;

FIG. 13 is a top-view schematic diagram of a package structure of the memory card according to one embodiment of the present invention;

FIG. 14 is a cross-sectional schematic diagram of a chip package according to one embodiment of the present invention;

FIG. 15 is a top-view schematic diagram of a package structure of the memory card according to one embodiment of the present invention; and

FIG. 16 is a process flow chart for a package method of the memory card according to one embodiment of the present invention.

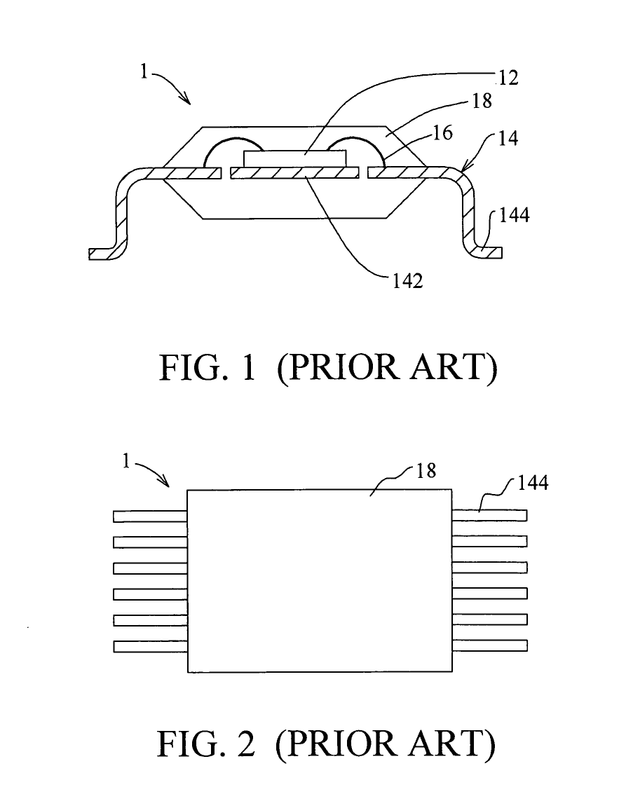

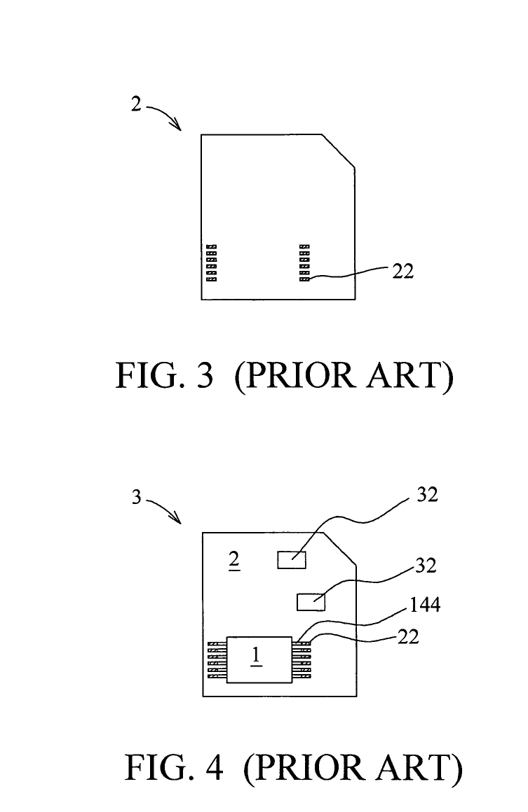

### DESCRIPTION OF THE PREFERRED EMBODIMENT

The detailed explanation of the present invention is described as following. The described preferred embodiments are presented for purposes of illustrations and description, and they are not intended to limit the scope of the present invention.

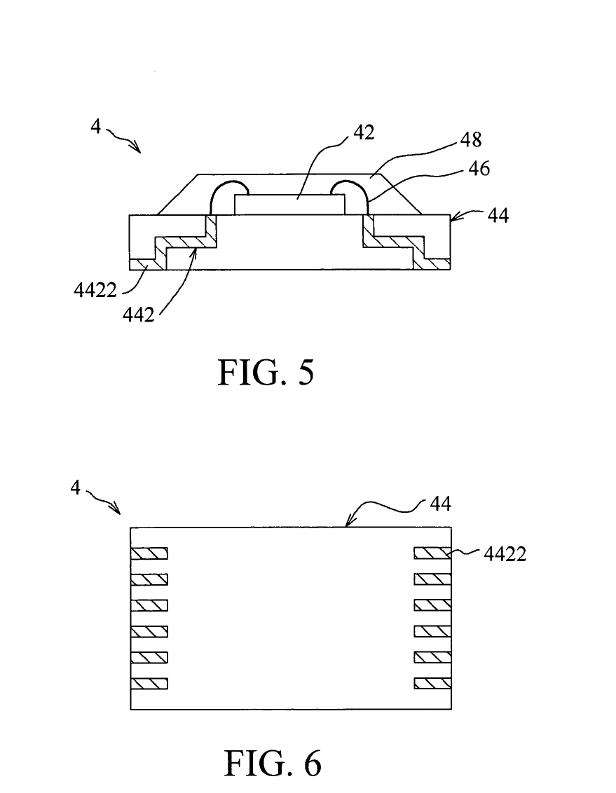

FIG. 5 and FIG. 6 are the cross-sectional and top-view schematic diagrams of the chip package 4 respectively according to one embodiment of the present invention. A chip 42 is set on the upper surface of a substrate 44 that has a layer of trace 442 inside, and the trace 442 has a plurality of conductive terminals 4422 exposed on the bottom surface of the substrate 44. A plurality of bonding wires 46 are set to electrically connect the chip 42 and the substrate 44, and a molding compound 48 covers the bonding wires 46, the upper surface of the substrate 44 and the chip 42, which the bottom surface of the substrate 44 are exposed to the molding compound 48. In one embodiment, the material of the molding compound 48 is epoxy resin.

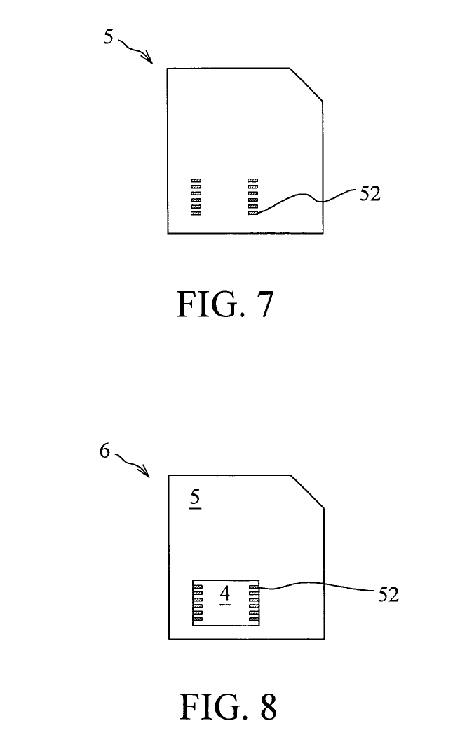

FIG. 7 is a top-view schematic diagram of a PCB 5 according to one embodiment of the present invention, which a plurality of solder pads 52 are set on the upper surface of the PCB 5.

FIG. 8 is a top-view schematic diagram of a package structure of the memory card 6 according to one embodiment of the present invention. The chip package 4 is set on the upper surface of the PCB 5, and the conductive terminals 4422 (shown in FIG. 6) are adhered to and electrically connected with the solder pads 52.

Accordingly, one feature of the package structure of the memory card according to the present invention is that it includes a chip package and adopts a substrate as the chip carrier. Therefore, the package structure of the memory card according to the present invention may be applied for the memory card with different sizes, shapes and specifications, for example, the SD card, mini SD card, SD card, MMC and CF card, etc., but is not limited to the description herein.

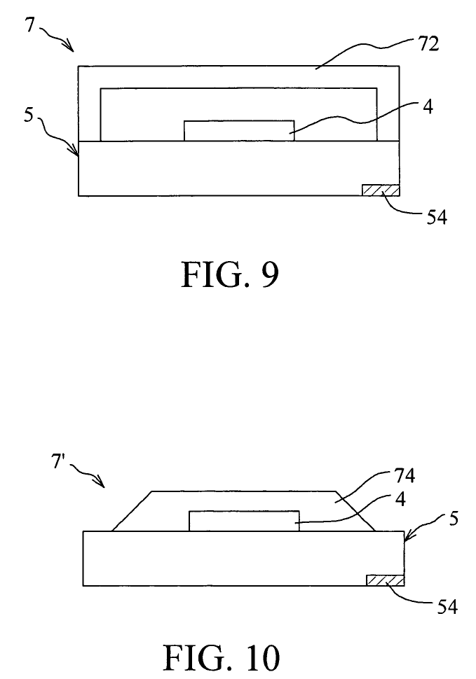

To continue the above description, a lid or a molding compound can be utilized to cover the chip package and the upper surface of the PCB to protect the memory card from the damage caused by the external force or the particle pollution after completing the adhesion of the chip package. Please refer to FIG. 9, which is a cross-sectional schematic diagram of a package structure of the memory card 7 according to one embodiment of the present invention. A lid 72 is used to cover the chip package 4 and the upper surface of the PCB 5 and expose the bottom surface of the PCB 5. A golden finger 54 is exposed on the bottom surface of the PCB 5. When the memory card is inserted into an insertion slot of an electronic apparatus (not shown in the figure), the golden finger 54 is used to serve as the electrical terminals between the electronic apparatus and the memory card for transmitting electrical power source and exchanging data. Please refer to FIG. 10, which is a cross-sectional schematic diagram of a package structure of the memory card 7′ according to another embodiment of the present invention. The package structure of the memory card 7′ applies a molding compound 74 to cover the chip package 4 and the upper surface of the PCB 5, which is different from the package structure of the memory card 7 in FIG. 9.

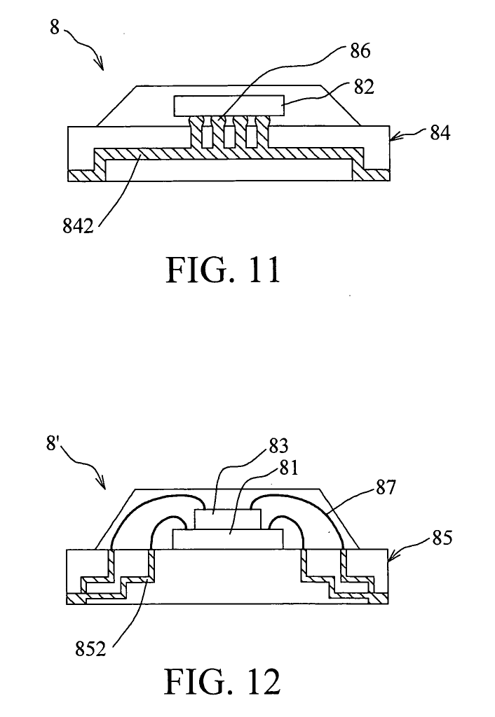

It can be appreciated for the people skilled in the art that the present invention may be applied to versatile chips and chip packages, such as a flash memory chip or a DRAM. Furthermore, the chip package, which adopts a substrate as the chip carrier according to the present invention, can be applied to various kinds of different package structures, such as the flip chip package. Please refer to FIG. 11, which is a cross-sectional schematic diagram of a chip package 8 according to one embodiment of the present invention. The chip package 8 is a flip chip package, wherein the active surface of the chip 82 faces the upper surface of the substrate 84, and a plurality of solder balls 86 are set to electrically connect the chip 82 and the trace 842 of the substrate 84.

Because the chip package of the present invention adopts a substrate as the chip carrier, it has enough space inside the chip carrier to apply the St. MCP. Please refer to FIG. 12, which is a cross-sectional schematic diagram of a chip package 8′ according to another embodiment of the present invention. The chip package 8′ is a St. MCP, wherein the chip 81 and the chip 83 are stacked on the substrate 85. In this embodiment, the chip 81 and the chip 83 are electrically connected with the substrate 85 via the bonding wires 87. It also may apply other ways, such as the solder balls. Therefore, according to the spirit of the present invention, all the package structures of the memory card that adopt a chip package and utilize a substrate as the chip carrier are enclosed in the scope of the present invention, they are not further described herein.

In addition, another advantage for adopting a substrate as the chip carrier is that multi layers of traces may be set inside the substrate to increase the freedom and flexibility for the package design. For instance, please refer to FIG. 12 again, there are two layers of traces 852 set inside the substrate 85.

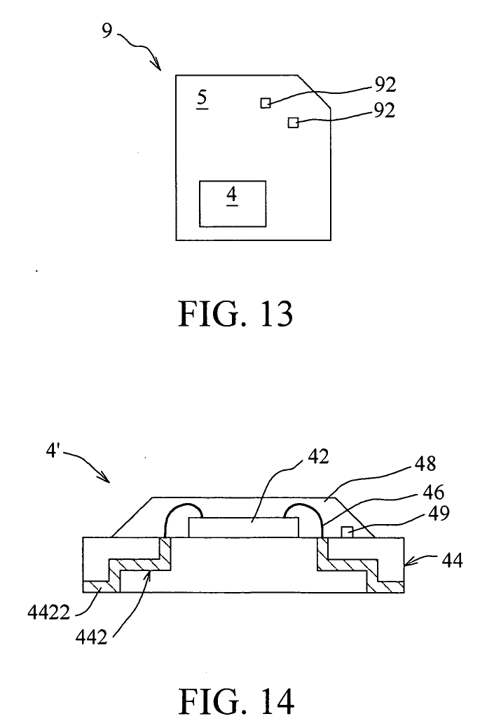

Generally, the memory card needs the passive elements, such as the transistors, capacitors and inductors to achieve noise filtering and other functions. Please refer to FIG. 13, which is a top-view schematic diagram of a package structure of the memory card 9 according to one embodiment of the present invention. The chip package 4 is set on the upper surface of the PCB 5, and the passive elements 92 are also set on the upper surface of the PCB 5 and electrically connected with the PCB 5.

Furthermore, because the present invention adopts a substrate as the chip carrier, there is larger space inside the chip package. Thus, the passive elements including transistors, capacitors or inductors can be packaged inside the chip package to save the package space of the PCB. Please refer to FIG. 14, which is a cross-sectional schematic diagram of a chip package 4′ according to one embodiment of the present invention. The chip package 4′ includes at least one passive element 49 set on the upper surface of the substrate 44 and electrically connected with the substrate 44.

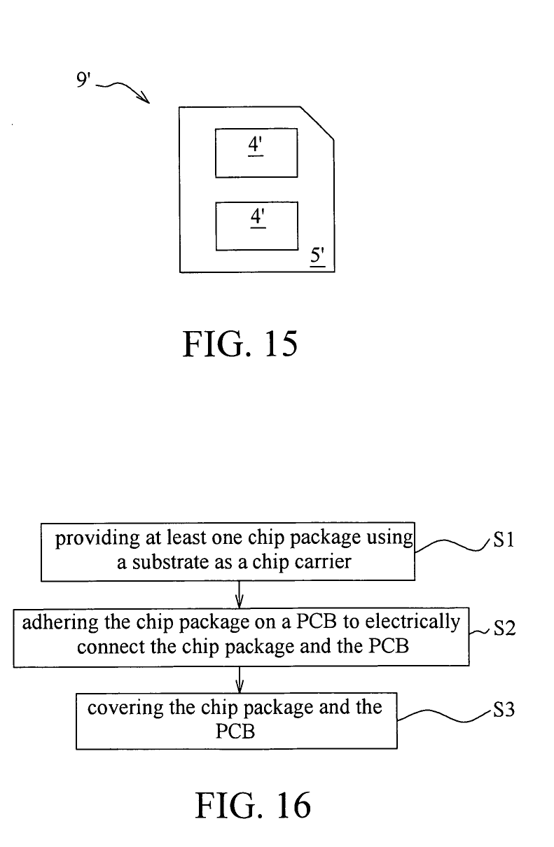

As the aforementioned description, the passive elements of the present invention can be packaged inside the chip package. Therefore, the saved package space of the PCB can be supplied to package more than one chip package into the same memory card. Please refer to FIG. 15, which is a top-view schematic diagram of a package structure of the memory card 9′ according to one embodiment of the present invention. There are two chip packages 4′ set on the PCB 5′ to increase functions and storage capacity of the memory card.

To sum up, there are many advantages for the chip package of the memory card that adopts a substrate as the chip carrier according to the present invention, which include: 1. Multi layers of traces can be set inside the substrate to increase the freedom and flexibility for the package design, and the St. MCP can be applied to increase functions and storage capacity of the memory card; 2. The passive elements of the present invention can be packaged inside the chip package. Thus, more than one chip package is capable to be packaged into the same memory card to further increase functions and storage capacity.

On the other hand, FIG. 16 is a process flow chart for a package method of the memory card according to one embodiment of the present invention, The steps of the package method include: step 1 S1, providing at least one chip package using a substrate as a chip carrier; step 2 S2, adhering the chip package onto a PCB to electrically connect the chip package and the PCB; and step 3 S3, covering the chip package and the PCB.

In one embodiment, a lid or a molding compound can be used to cover the chip package and the PCB, and the material of the molding compound may be epoxy resin. Besides, the package method for a memory card according to present invention may includes adhering at least one passive element onto the PCB.

Consequently, the package method for a memory card according to present invention has the advantages including simple steps, compatibility with the conventional process and easy implementation.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. A package structure of a memory card, comprising:
a Printed Circuit Board (PCB) having a first upper surface and a first bottom surface, wherein an exposed golden finger is set on said first bottom surface of said PCB and a plurality of solder pads are set on said first upper surface of said PCB; and
at least one chip package, comprising:
at least one chip; and
a substrate, wherein said substrate has a second upper surface and a second bottom surface, said chip is set on said second upper surface, and at least one layer of trace is set inside said substrate;
wherein said layer of trace has a plurality of conductive terminals exposed on said second bottom surface, and said to said solder pads.

2. The package structure of a memory card according to claim 1, comprising a lid covering said first upper surface of said PCB and said chip package and exposing said first bottom surface of said PCB.

3. The package structure of a memory card according to claim 1, comprising a molding compound covering said first upper surface of said PCB and said chip package and exposing said first bottom surface of said PCB.

4. The package structure of a memory card according to claim 3, wherein said material of said molding compound is epoxy resin.

5. The package structure of a memory card according to claim 1, comprising at least one passive element set on said first upper surface of said PCB and electrically connected with said PCB.

6. The package structure of a memory card according to claim 5, wherein said passive element is a transistor, a capacitor or an inductor.

7. The package structure of a memory card according to claim 5, wherein said chip package comprises a plurality of bonding wires to electrically connect said chip and said substrate.

8. The package structure of a memory card according to claim 1, wherein said chip package comprises at least one molding compound covering said second upper surface of said substrate and said chip and exposing said second bottom surface of said substrate.

9. The package structure of a memory card according to claim 8, wherein said material of said molding compound is epoxy resin.

10. The package structure of a memory card according to claim 1, wherein said chip package is a Stacked-type Multi Chip Package (St. MCP) comprising a plurality of chips stacked on said substrate and electrically connected with said substrate.

11. The package structure of a memory card according to claim 10, comprising a plurality of bonding wires to electrically connect said chips and said substrate.

12. The package structure of a memory card to claim 1, wherein said chip package is a flip chip package, said active surface of said chip faces said second upper surface and a plurality of solder balls are set to electrically connect said chip and said layer of trace of said substrate.

13. The package structure of a memory card according to claim 1, wherein said chip package comprises at least one passive element set on said second upper surface of said substrate and electrically connected with said substrate.

14. The package structure of a memory card according to claim 13, wherein said passive element is a transistor, a capacitor or an inductor.

15. The package structure of a memory card according to claim 1, wherein said memory card is a Secure Digital card (SD card), a mini SD card, a micro SD card (μSD card), a Multi Media Card (MMC) or a Compact Flash card (CF card).

16. The package structure of a memory card according to claim 1, wherein said chip package is a Dynamic Random Access Memory (DRAM).

17. The package structure of a memory card according to claim 1, wherein said chip is a flash memory chip.

18. A package method for a memory card, comprising:
providing at least one chip package using a substrate as a chip carrier;
adhering said chip package onto a PCB to electrically connect said chip package and said PCB; and
covering said chip package and said PCB.

19. The package method for a memory card according to claim 18, comprising adhering at least one passive element onto said PCB.

20. The package method for a memory card according to claim 18, wherein a lid is used for said covering said chip package and said PCB.

21. The package method for a memory card according to claim 18, wherein a molding compound is used for said covering said chip package and said PCB.

22. The package method for a memory card according to claim 19, wherein said material of said molding compound is epoxy resin.
